(19) United States
(12) Patent Application Publication
(10) Pub. No.: US 2009/0146768 A1
(43) Pub. Date: Jun. 11, 2009

(54) MAGNETIC DEVICE UNIT AND FIXING COMPONENT THEREOF

(75) Inventors: Ching-Hsien Teng, Taoyuan Hsien (TW); Hsin-Wei Tsai, Taoyuan Hsien (TW); Tzu-Yang Liu, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/024,314

(22) Filed: Feb. 1, 2008

(30) Foreign Application Priority Data
Dec. 11, 2007 (TW) 096147239

(51) Int. Cl. H01F 27/06

(52) U.S. Cl. 336/65

(57) ABSTRACT

A magnetic device unit disposed on a circuit board is disclosed. The magnetic device comprises a magnetic device and a fixing component. The magnetic device has a conductive wire wound thereon. The conductive wire has a terminal. The fixing component is disposed on the circuit board and comprises a main body and a pin. The pin comprises a first conductive portion, a second conductive portion and a connection portion connecting the first and second conductive portions, wherein the connection portion is embedded in the main body and the second conductive portion is connected to the circuit board. The magnetic device is carried by the main body of the fixing component and the terminal of the conductive wire is connected to the first conductive portion of the pin for the magnetic device to be electrically connected to the circuit board via the pin.

### FIELD OF THE INVENTION

The present invention relates to a magnetic device unit and the fixing component thereof, and more particularly to a magnetic device unit surface mounted on a circuit board through the fixing component.

### BACKGROUND OF THE INVENTION

Generally speaking, the circuit boards of electric products with electrical circuit comprise magnetic devices with inductance characteristic, so as to execute the functions of energy storage, wave filtration, current choke and resonance, etc.

Take choke coil as an example, it is a coiled magnetic device with conductive wire winding along the annular core. The choke coil can be disposed on the circuit board by inserting the terminals of the conductive wire directly into the pre-set through holes on the circuit board. The choke coil can also be disposed on the circuit board by bending the terminals of the conductive wire toward the direction that parallel to the circuit board and then soldered on the circuit board by surface mount technology (SMT), so as to support the choke coil via the bent terminals.

However, most of the choke coils are annular with thin conductive wires; thus the contact areas between the conductive wire and the circuit board are limited. When the circuit board is shocked, conductive terminals may not firmly support the choke coil on the circuit board and causes the choke coil to easily depart from the circuit board. Therefore, the function of the circuit board is impacted.

For solving the foregoing defects, a fixing component to serve as a media between the choke coil and the circuit board is developed, so as to surface mount the choke coil on the circuit board. Please refer to FIG. 1(a), which is a schematic diagram showing the structure of the conventional fixing component. As shown in FIG. 1(a), the fixing component 11 comprises a main body 111. The top surface of the main body 111 is a cambered concave surface 112 for carrying the choke coil 12 (as shown in FIG. 2). Two pins 113 and 114 are extended from one of the lateral wall of the main body 111 which parallels the axis of the choke coil 12, whereas two pins 115 and 116 are extended from the other lateral wall parallels to the axis of the choke coil 12. One ends of the pins 113, 114, 115 and 116 are embedded in the main body 111 (as shown in FIGS. 1(b) and 1(c)). The pins 113 and 114 extended from the same lateral wall are separated from and isolated to each other, and the pins 115 and 116 are separated from and isolated to each other as well (as shown in FIG. 1(c)).

Please refer to FIG. 2 and FIG. 1(a), while the choke coil 12 is disposed on the circuit board 1, the choke coil 12 can be carried by the cambered concave surface 112 of the fixing component 11. The terminal 121a of the conductive wire 121 of the choke coil 12 is wound on the winding portions 117 of the pins 113 and 114, and the other terminal 121b of the conductive wire 121 is wound on the winding portions 117 of the pins 115 and 116. The contact portions 118 of each of the pins 113-116 are contacted with the circuit board 1 via the contact pad 13 on the circuit board 1. Hence the choke coil 12 can be surface mounted on the circuit board 1 through the fixing component 11 and electrically connected to the circuit board 1 through the pins 113-116 (as shown in FIG. 2). Of course, if the choke coil comprises two conductive wires wound thereon, four terminals of the conductive wires can be wound on four pins 113, 114, 115 and 116, respectively.

Nevertheless, the volume of the fixing component 11 is small, and the conductive wire 121 of the choke coil 12 has a particular hardness. Thus it is not a simple task to wind the conductive wire 121 of the choke coil 12 on the pins 113-116. The pins 113-116 are easily deformed and the surface flatness thereof is decreased due to the force improperly applied thereto. It is to be understood that if two conductive wires are wound on the choke coil 12, the process to wind each of the four terminals on each of the pins is more difficult and time-consuming. Besides, the conductive wire 121 is wound on the choke coil 12 in the direction parallel to the axis of the choke coil 12; in other words, the winding direction of the conductive wire 121 is parallel to the lateral walls of the fixing component 11 with pins 113-116 disposed thereon. Hence longer terminals 121a and 121b have to be reserved for the terminals 121a and 121b to be in contact with pins 113-116 and further wound on the winding portions 117. Accordingly, the material cost is raised.

In addition, if a thicker conductive wire 121 is wound on the choke coil 12 for higher inductance, the difficulty level for winding the conductive wire 121 on the pins 113-116 is increased correspondingly. Moreover, the region of the winding portions 117 of the pins 113-116 for winding the conductive wire 121 is limited; therefore, insufficient space of winding portion 117 may force conductive wire 121 to wind on the contact portion 118 and influence the flatness of the pins 113-116. If the fixing component 11 cannot be flatly mounted on the circuit board 1, the efficiency of the circuit board 1 will be impacted directly or indirectly.

Accordingly, it is required to develop a magnetic device unit and the fixing component thereof to firmly carry the magnetic device and electrically connect the magnetic device and the circuit board through the fixing component, so as to simplify the process steps for assembling the magnetic device and the fixing component, raise the yield, shorten the fabricating procedure and lower the cost to overcome the foregoing defects.

### SUMMARY OF THE INVENTION

An object of the present invention is to provide a magnetic device unit and the fixing component thereof. The first conductive portion and the second conductive portion of the pin are electrically connected to the conductive wire of the magnetic device and the circuit board, respectively, and the first and second conductive portions are connected to each other via the connection portion embedded in the main body of the fixing component. Therefore, the magnetic device can be carried by the fixing component and further flatly disposed on and electrically connected to the circuit board through the fixing component and the pin thereof, so as to avoid the problems of the conventional fixing component that the pins cannot be disposed on the circuit board flatly due to the conductive wire wound thereon. The processing procedure for assembling the magnetic device and the fixing component can also be simplified.

According to an aspect of the present invention, a magnetic device unit is provided. The magnetic device unit is disposed on a circuit board and comprises a magnetic device and a fixing component. The magnetic device has a conductive wire wound thereon, and the conductive wire has a terminal. The fixing component is disposed on the circuit board and comprises a main body and a pin. The pin comprises a first conductive portion, a second conductive portion and a connection portion connecting the first and second conductive portions. The connection portion is embedded in the main body, and the second conductive portion is connected to the circuit board. The magnetic device is carried by the main body of the fixing component, and the terminal of the conductive wire is connected to the first conductive portion of the pin for the magnetic device to be electrically connected to the circuit board via the pin.

In an embodiment, the main body of the fixing component comprises a carrying surface for carrying the magnetic device, a bottom surface corresponded to the carrying surface and substantially contacted with the circuit board, and a lateral sidewall adjacent to the carrying surface and the bottom surface. The carrying surface is a cambered concave surface. The first conductive portion is extended from the lateral sidewall, whereas the second conductive portion is extended from the bottom surface.

In an embodiment, the magnetic device is substantially annular, and the axis of the magnetic device is perpendicular to the lateral sidewall of the main body.

In an embodiment, the first conductive portion of the pin is partially embedded in the main body. Whereas the first conductive portion exposed relative to the main body is substantially parallel to the second conductive portion or extended toward the carrying surface to define a receiving slit with the lateral sidewall for receiving the terminal of the conductive wire, so as to electrically connect the conductive wire and the pin.

In an embodiment, the first conductive portion of the pin of the fixing component further comprises a hole to receive the terminal of the conductive wire.

In an embodiment, the first conductive portion, the connection portion and the second conductive portion of the pin are integrally formed.

In an embodiment, the magnetic device unit further comprises a connecting media disposed between the magnetic device and the carrying surface of the fixing component.

In an embodiment, the fixing component is surface mounted on the circuit board.

According to another aspect of the present invention, there is provided a fixing component for disposing a magnetic device on a circuit board. The magnetic device substantially has a conductive wire wound thereon, and the conductive wire has a terminal. The fixing component comprises a main body and a pin, wherein the main body is applied for carrying the magnetic device. The pin has a first conductive portion for connecting to the terminal of the conductive wire of the magnetic device, a second conductive portion for connecting to the circuit board, and a connection portion being embedded in the main body and connecting the first and second conductive portions. The magnetic device is disposed on and electrically connected to the circuit board through the fixing component.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1(a) is a schematic diagram showing the structure of the conventional fixing component;

FIG. 1(b) is the A-A′ cross-section view of FIG. 1(a);

FIG. 1(c) is the B-B′ cross-section view of FIG. 1(a);

FIG. 2 is a schematic diagram showing the choke coil disposed on the circuit board through the conventional fixing component shown in FIG. 1(a);

FIG. 3(a) is a schematic diagram showing the magnetic device unit disposed on the circuit board according to a first preferred embodiment of the present invention;

FIG. 3 (b) is a lateral view of FIG. 3(a);

FIG. 4(a) is a schematic diagram showing the structure of the fixing component shown in FIG. 3(a);

FIG. 4(b) is the A-A′ cross-section view of FIG. 4(a);

FIG. 5(a) is a schematic diagram showing the structure of the fixing component according to a second preferred embodiment of the present invention;

FIG. 5(b) is the A-A′ cross-section view of FIG. 5(a); and

FIG. 6 is a cross-section view of a magnetic device unit with the fixing component shown in FIG. 5(a).

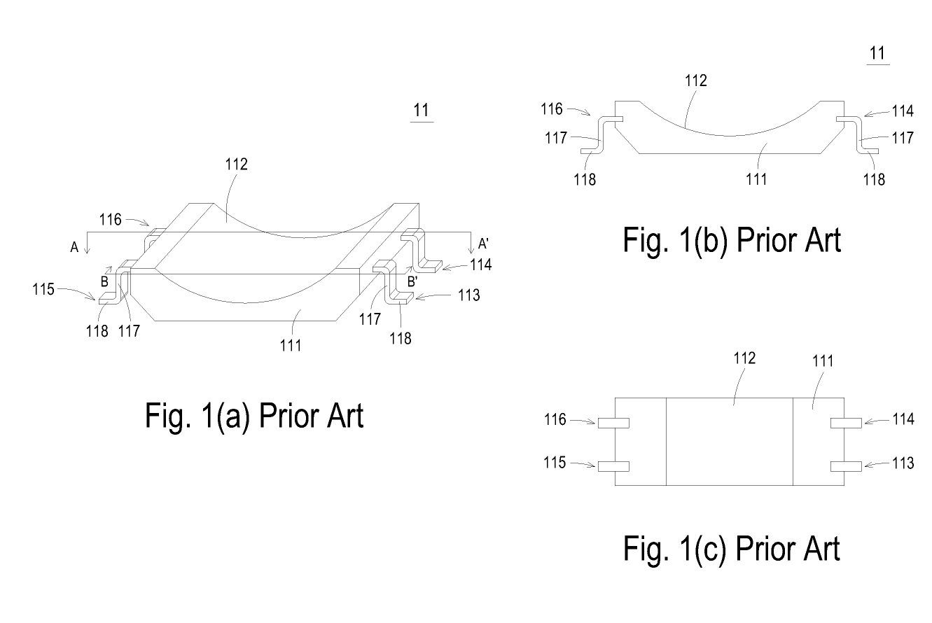

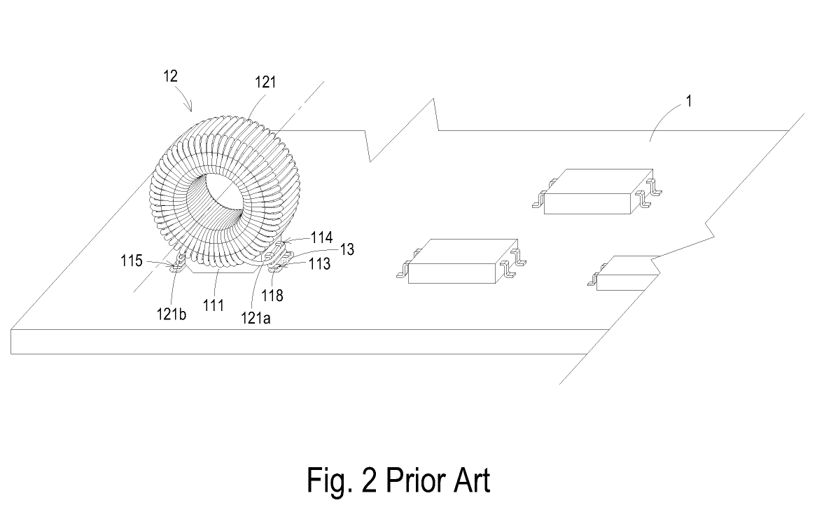

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

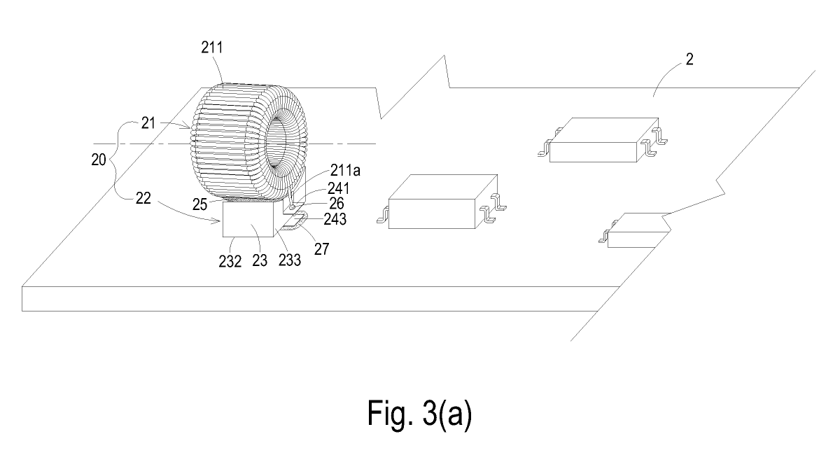

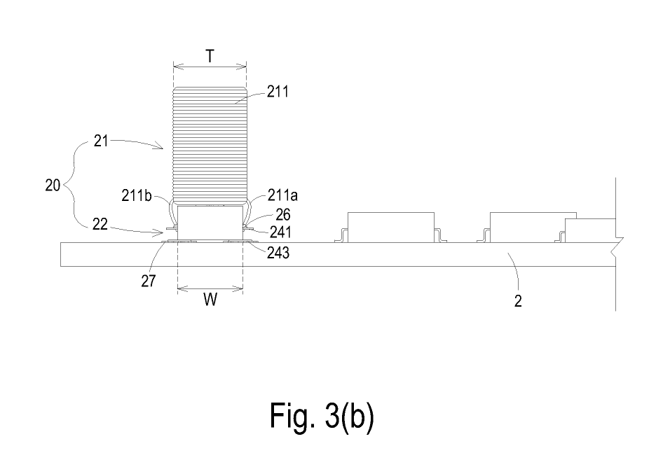

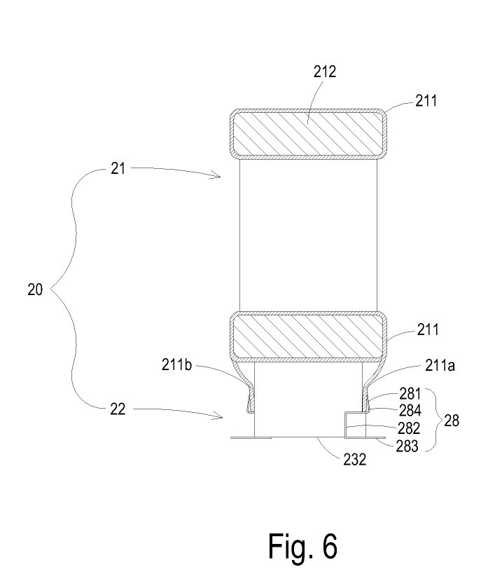

Please refer to FIGS. 3(a) and 3(b), which are schematic diagram and lateral view showing the magnetic device unit disposed on the circuit board according to the first embodiment of the present invention. As shown in FIGS. 3(a) and 3(b), the magnetic device unit 20 comprises a magnetic device 21 and a fixing component 22. The magnetic device 21 can be a device that generates the electromotive force by current variation, such as choke coil, but not limited thereto. The magnetic device 21 has a core 212 (as shown in FIG. 6) and at least a conductive wire 211. The core 212 can be an annular core, and the conductive wire 211 is wound on the core 212 along the direction parallel to the axis of the core 212, so as to wrap the core 212. The conductive wire 211 has terminals 211a and 211b. In some embodiments, the conductive wire 211 can be enameled wire, but not limited thereto. In addition, the terminals 211a and 211b of the conductive wire 211 is de-enameled for electrically connecting to the fixing component.

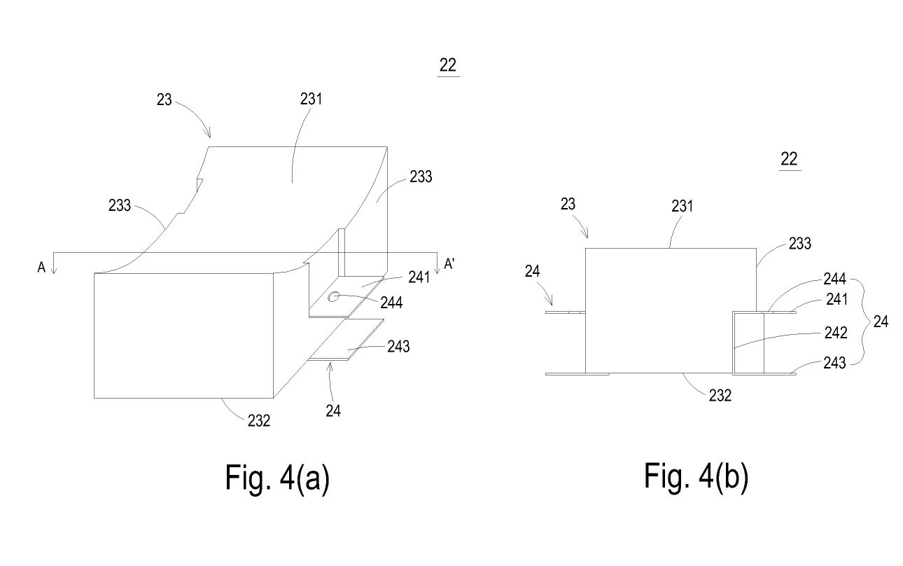

Please refer to FIG. 4(a) and FIGS. 3(a) and 3(b), wherein FIG. 4(a) is a schematic diagram showing the structure of the fixing component shown in FIG. 3(a) of the present invention. The fixing component 22 comprises a main body 23, wherein the main body 23 is substantially a rectangular cubic. The main body 23 has a carrying surface 231, a bottom surface 232, and two lateral sidewalls 233 adjacent to the carrying surface 231 and the bottom surface 232. In this embodiment, the carrying surface 231 can be a cambered concave surface, and the width W thereof is substantially smaller than the thickness T of the magnetic device 21, so as to match the thickness T of the magnetic device 21 and carry the annular magnetic device 21 via the radian of the carrying surface 231. Hence the magnetic device 21 can be disposed on the carrying surface 231 of the main body 23. The lateral sidewalls 233 are the corresponding sides of the main body 23 perpendicular to the axis of the magnetic device 21. In other words, as shown in FIG. 4(a), the lateral sidewalls 233 defined in the embodiment of the present invention is located at the longer side of the rectangular main body 23. The bottom surface 232 of the main body 23 is corresponded to the carrying surface 231 and substantially contacts with the circuit board 2 while the fixing component 22 is disposed on the circuit board 2. Besides, the fixing component 22 comprises not only the main body 23 but also the pins 24. The number of the pins 24 in the present invention can be even, such as two, but not limited thereto. That is to say, the number of pins 24 of the present invention is not restricted, and the number of pins 24 can be adjusted according to the number of the conductive wire 211 wound on the magnetic device 21. For example: when one conductive wire 211 is wound on the magnetic device 21, the conductive wire 211 has two terminals 211a and 211b. Therefore, two pins 24 can be disposed on the main body 23 of the fixing component 22. Similarly, it can be inferred that when two conductive wires 211 are wound on the magnetic device 21, four pins 24 can be disposed on the fixing component 22 in cooperation with four terminals of the conductive wire 211.

Please refer to FIGS. 4(b) and 4(a), wherein FIG. 4(b) is the A-A′ cross-section view of FIG. 4(a). As shown in FIGS. 4(a) and 4(b), the pin 24 is partially protruded from the later sidewall 233 of the main body 23. The pin 24 substantially has three portions: the first conductive portion 241, the connection portion 242, and the second conductive portion 243. The first conductive portion 241 and the second conductive portion 243 are disposed at the opposite ends of the connection portion 242. In other words, the first and second conductive portions 241 and 243 are connected to each other through the connection portion 242. In this embodiment, the main body 23 can be molded plastic. The first conductive portion 241, the connection portion 242, and the second conductive portion 243 of the pin 24 can be formed by bending an electrical conductive material, such as a metal plate. That is to say, the first conductive portion 241, the connection portion 242 and the second conductive portion 243 are integrally formed. The connection portion 242 of the pin 24 is embedded in the main body 23, and the end of the first conductive portion 241 connected to the connection portion 242 is partially embedded in the main body 23 as well. The other end of the first conductive portion 241 not embedded in the main body 23 is exposed relative to the main body 23 and extended from the lateral sidewall 233. As regards, the second conductive portion 243 is exposed relative to the main body 23, extended from the bottom surface 232 of the main body 23 and close to the bottom surface 232.

In addition, the included angles between the first conductive portion 241 and the connection portion 242, and between the connection portion 242 and the second conductive portion 243 are substantially 90°. In other words, the first conductive portion 241 and the second conductive portion 243 are parallelly protruded from the lateral sidewall 233 of the main body 23. A hole 244 can be formed at the exposed first conductive portion 241, so as to receive the terminals 211a and 211b of the conductive wire 211 of the magnetic device 21 through the holes 244 (as shown in FIG. 3(b)). Accordingly, the fixing component 22 is electrically connected to the terminals 211a/211b of the conductive wire 211 and the circuit board 2 by the first conductive portion 241 and the second conductive portion 243 thereof, respectively (as shown in FIG. 3(b)). Of course, the terminals 211a and 211b of the conductive wire 211 can be wound on the first conductive portion 241 for electrically connecting the conductive wire 211 and the pin 24.

Please refer to FIG. 3(a) and FIG. 3(b) again, the magnetic device 21 is disposed on the carrying surface 231 of the main body 23 of the fixing component 22 for assembling the magnetic device 21 and the fixing component 22 to form the magnetic device unit 20. Since the radian of the carrying surface 231 matches the annular magnetic device 21, the magnetic device 21 can be supported by the carrying surface 231 and further disposed on the main body 23. Of course, in some embodiments, the connecting media 25, such as adhesive, can be filled between the magnetic device 21 and the carrying surface 231 of the main body 23 of the fixing component 22, so as to firmly fix the magnetic device 21 on the carrying surface 231 of the main body 23 of the fixing component 22. The conductive wire 211 of the magnetic device 21 is wound on the core 212 in the direction parallel to the axis of the core 212, the lateral sidewalls 233 of the main body 23 of the fixing component 22 are perpendicular to the axis of the magnetic device 21, and the thickness T of the magnetic device 21 is larger than the width W of the carrying surface 231 of the main body 23. Therefore, the terminals 211a and 211b of the conductive wire 211 can be directly inserted into the hole 244 on the first conductive portion 241 of the pin 24 by bending the terminals 211a and 211b parallel to the axis of the magnetic device 21 toward the fixing component 22 after the conductive wire 211 is wound on the core 212, so as to electrically connect the conductive wire 211 and the pin 24.

To improve the structural strength, the solder 26 can be further applied to the terminals 211a/211b of the conductive wire 211 and the first conductive portion 241 of the pin 24. Thus the conductive wire 211 can be electrically connected to the pin 24 firmly after soldering process, so as to assemble the magnetic device unit 20 of the embodiment of the present invention. The magnetic device unit 20 can be disposed on the surface of the circuit board 2 by attaching the bottom surface 232 of the main body 23 of the fixing component 22 to the circuit board 2. The second conductive portion 243 of the pin 24 is contacted with the pre-set location on the circuit board 2, such as contact pad 27, but not limited thereto. Therefore, the second conductive portion 243 of the pin 24 can be electrically connected to the circuit board 2 after soldering. Accordingly, the fixing component 22 can be firmly surface mounted on the circuit board 2, and the magnetic device 21 can be secured on the circuit board 2 through the fixing component 22. In addition, the magnetic device 21 is electrically connected to the circuit board 2 through the route of terminals 211a/211b of the conductive wire 211, the first conductive portion 241, the connection portion 242, the second conductive portion 243 and the contact pad 27.

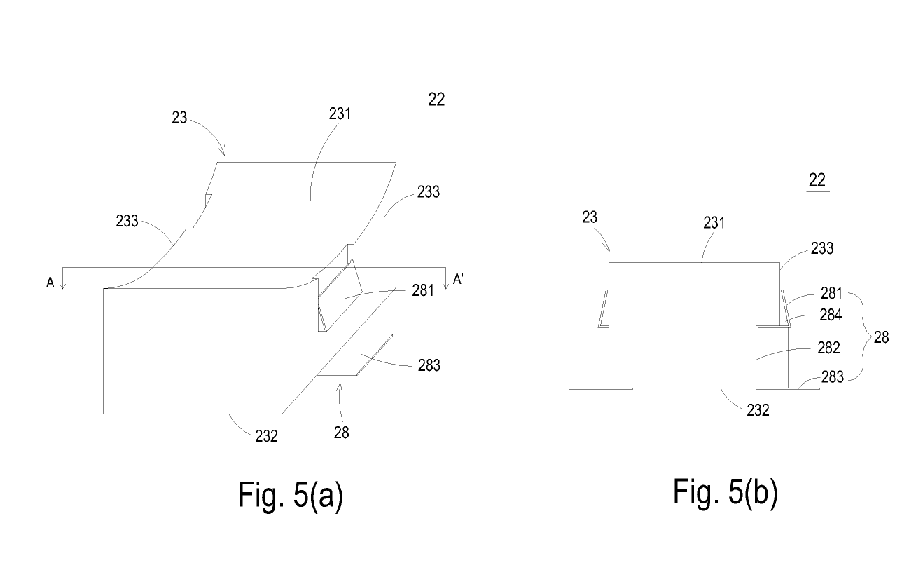

Of course, the fixing component of the present invention is not limited to the foregoing embodiment. Please refer to FIG. 5(a) and FIG. 5(b), wherein FIG. 5(a) is a schematic diagram showing the structure of the fixing component according to the second preferred embodiment of the present invention and FIG. 5(b) is the A-A′ cross-section view of FIG. 5(a). As shown in FIGS. 5(a) and 5(b), the main body 23 of the fixing component 22 is similar to that shown in FIG. 4(a), and thus it is not redundantly described here. In this embodiment, the fixing component 22 also comprises the pin 28. The pin 28 has a first conductive portion 281, a connection portion 282, and a second conductive portion 283. The disposition of the second conductive portion 283 and the connection portion 282 and the structural relationships among the main body 23, the second conductive portion 283, and the connection portion 282 are the same as that shown in FIGS. 4(a) and 4(b). In this embodiment, the first conductive portion 281 exposed relative to the main body 23 is bent toward the carrying surface 231 of the main body 23. Hence the first conductive portion 281 protruded out of the lateral sidewall 233 is extended toward the carrying surface 231, so as to define a receiving slit 284 by the first conductive portion 281 and the lateral sidewall 233 of the main body 23 to receive the terminals 211a and 211b of the conductive wire 211 of the magnetic device 21. It is to be understood that the terminals 211a and 211b of the conductive wire 211 can be directly inserted into the receiving slit 284 by bending the terminals 211a and 211b parallel to the axis of the of the magnetic device 21 toward the fixing component 22 after the conductive wire 211 is wound on the core 212. Thus the terminals 211a and 211b can be held by the first conductive portion 281 and the lateral sidewall 233 of the main body 23 of the fixing component 22 for electrically connecting the conductive wire 211 and the pin 28 (as shown in FIG. 6). In some embodiments, the solder (not shown) can be filled in the receiving slit 284 and the soldering process can be performed to ensure the electrical connection between the terminals 211a/211b of the conductive wire 211 of the magnetic device 21 and the first conductive portion 281 of the pin 28 of the fixing component 22, so as to assemble the magnetic device unit 20. The electric route between the magnetic device unit 20 and the circuit board is the same as that of the first embodiment shown in FIGS. 3(a) and 3(b); hence it is not redundantly described.

It is to be understood that the first and second conductive portions of the pins of the fixing component not only can be disposed on the lateral sidewalls perpendicular to the axis of the magnetic device, but also can be disposed on the lateral sidewalls parallel to the axis of the magnetic device depending on the requirement. The flatness of the magnetic device unit disposed on the circuit board is not impacted by the location of the pin; of course, the magnetic device can be electrically connected to the circuit board through the pin of the fixing component as well. In other words, all the designs that connect the conductive wire of the magnetic device and circuit board respectively through the first and second conductive portions of the pin of the fixing component, and link the first and second conductive portions through the connection portion embedded within the main body of the fixed component device belong to the invention concept of the present invention.

According to the foregoing descriptions, it is to be understood that the magnetic device of the present invention is flatly and firmly disposed on the circuit board via the fixing component supported thereto. The conductive wire of the magnetic device is electrically connected to the circuit board through the pin of the fixing component. Compared to the conventional technology, the pin of the fixing component of the present invention comprises a first conductive portion, a connection portion, and a second conductive portion. Therefore, the terminals of the conductive wire of the magnetic device and the circuit board can be respectively connected to the first and second conductive portions of the pin, and the first and second conductive portions are connected to each other through the connection portion embedded in the main body. In other words, since the first and second conductive portions of the pin are connected to each other through the connection portion embedded in the main body of the fixing component, the flatness of the second conductive portion surface mounted on the circuit board is not impacted by the first conductive portion with conductive wire wound thereon. The structure of the pin of the present invention is different from that of the pin of the conventional fixing component, wherein the winding portion of the conventional pin for winding wire is directly connected to the contact portion. Accordingly, the problem that the conventional fixing component cannot flatly surface mounted on the circuit board due to the conductive wire of the choke coil wound on the winding portion of the pin can be prevented.

Besides, since the hole can be disposed on the first conductive portion of the pin, or the receiving slit can be defined by the lateral sidewall of the main body and the first conductive portion of the pin, the terminal of the conductive wire of the magnetic device can be directly inserted into the hole or the receiving slit. Hence the step for winding the conductive wire of the choke coil on the winding portion of the pin of the conventional fixing component can be omitted, the process procedure for assembling the magnetic device unit can be simplified, and the yield can be raised. It is to be understood that when the conductive wire with different thickness is wound on the magnetic device for different electro-magnetic characteristic, the sizes of the hole and the receiving slit can be correspondingly adjusted for the terminal of the conductive wire to be directly inserted therein, so as to electrically connect the conductive wire and the pin. Of course, when the number of the conductive wires wound on the magnetic device is increased, the number of the pins can be increased accordingly, so as to match the number of the terminals of the conductive wires. Therefore, each of the terminals of the conductive wire can be connected to each of the first conductive portions of the pins, and the inconvenience for winding plural conductive wires or winding a thicker conductive wire on the pin in the conventional technology can be prevented as well.

Moreover, the conductive wire is wound on the magnetic device in the direction parallel to the axis of the magnetic device; therefore, when the pin is protruded from the lateral sidewalls perpendicular to the axis of the magnetic device, the terminals of the conductive wire can be directly connected to the first conductive portion of the pin by bending downwardly without wasting additional conductive wire for winding on the pin. Accordingly, the material of the conductive wire can be saved, and the cost can be lowered as well. The foregoing purposes cannot be achieved by the conventional technology, and thus the magnetic device unit and the fixing component thereof is novel and non-obvious.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A magnetic device unit, said magnetic device unit being disposed on a circuit board and comprising:
a magnetic device with a conductive wire wound thereon, said magnetic device being substantially annular, and said conductive wire having a terminal;
a fixing component disposed on said circuit board and comprising a main body and a pin, said pin comprising a first conductive portion, a second conductive portion and a connection portion connecting said first conductive portion and said second conductive portion, said connection portion being embedded in said main body, said first conductive portion being extended from a lateral sidewall of said main body, and said second conductive portion being connected to said circuit board;
wherein said magnetic device is carried by said main body of said fixing component with the axis of said magnetic device substantially being perpendicular to said lateral sidewall of said main body, and said terminal of said conductive wire is connected to said first conductive portion of said pin for said magnetic device to be electrically connected to said circuit board via said pin.

2. The magnetic device unit according to claim 1, wherein said main body of said fixing component comprising:
a carrying surface for carrying said magnetic device;
a bottom surface corresponded to said carrying surface and substantially contacted with said circuit board; and
said lateral sidewall adjacent to said carrying surface and said bottom surface;
wherein said second conductive portion is extended from said bottom surface.

3. (canceled)

4. The magnetic device unit according to claim 2, wherein said carrying surface of said main body of said fixing component is a cambered concave surface.

5. The magnetic device unit according to claim 2, wherein said first conductive portion of said pin of said fixing component is partially embedded in said main body, and said first conductive portion exposed relative to said main body is substantially parallel to said second conductive portion.

6. The magnetic device unit according to claim 2, wherein said first conductive portion of said pin of said fixing component is partially embedded in said main body, and said first conductive portion exposed relative to said main body is extended toward said carrying surface to define a receiving slit with said lateral sidewall for receiving said terminal of said conductive wire so as to electrically connect said conductive wire and said pin.

7. The magnetic device unit according to claim 1, wherein said first conductive portion of said pin of said fixing component further comprises a hole to receive said terminal of said conductive wire so as to electrically connect said conductive wire and said pin.

8. The magnetic device unit according to claim 1, wherein said first conductive portion, said connection portion and said second conductive portion of said pin are integrally formed.

9. The magnetic device unit according to claim 2 further comprising a connecting media disposed between said magnetic device and said carrying surface of said fixing component.

10. The magnetic device unit according to claim 1, wherein said fixing component is surface mounted on said circuit board.

11. A fixing component for disposing a magnetic device on a circuit board, said magnetic device substantially being annular and having a conductive wire wound thereon, said conductive wire having a terminal, said fixing component comprising:
a main body for carrying said magnetic device and having a lateral sidewall substantially perpendicular to the axis of said magnetic device; and
a pin comprising:
a first conductive portion for connecting to said terminal of said conductive wire of said magnetic device, said first conductive portion being extended from said lateral sidewall of said main body;
a second conductive portion for connecting to said circuit board; and
a connection portion being embedded in said main body and connecting said first conductive portion and said second conductive portion;
wherein said magnetic device is disposed on and electrically connected to said circuit board through said fixing component.

12. The fixing component according to claim 11, wherein said main body further comprising:
a carrying surface for carrying said magnetic device;
a bottom surface corresponded to said carrying surface and substantially contacted with said circuit board; and
said lateral sidewall adjacent to said carrying surface and said bottom surface;
wherein said second conductive portion is extended from said bottom surface.

13. (canceled)

14. The fixing component according to claim 12, wherein said carrying surface of said main body is a cambered concave surface.

15. The fixing component according to claim 12, wherein said first conductive portion of said pin is partially embedded in said main body, and said first conductive portion exposed relative to said main body is substantially parallel to said second conductive portion.

16. The fixing component according to claim 12, wherein said first conductive portion of said pin is partially embedded in said main body, and said first conductive portion exposed relative to said main body is extended toward said carrying surface to define a receiving slit with said lateral sidewall for receiving said terminal of said conductive wire so as to electrically connect said conductive wire and said pin.

17. The fixing component according to claim 11, wherein said first conductive portion of said pin of said fixing component further comprises a hole to receive said terminal of said conductive wire so as to electrically connect said conductive wire and said pin.

18. The fixing component according to claim 11, wherein said first conductive portion, said connection portion and said second conductive portion of said pin are integrally formed.

19. The fixing component according to claim 12, wherein said magnetic device and said carrying surface of said fixing component further comprise a connecting media disposed therebetween.

20. The fixing component according to claim 11, wherein said fixing component is surface mounted on said circuit board.
